(19) United States
(12) Patent Application Publication
(10) Pub. No.: US 2022/0165833 A1
(43) Pub. Date: May 26, 2022

(54) DISPLAY PANEL AND DISPLAY APPARATUS

(71) Applicants: Chengdu BOE Optoelectronics Technology Co., Ltd., Chengdu (CN); BOE Technology Group Co., Ltd., Beijing (CN)

(72) Inventors: Wenqiang LI, Beijing (CN); Weifeng ZHOU, Beijing (CN); Ling SHI, Beijing (CN); Liqiang CHEN, Beijing (CN)

(21) Appl. No.: 17/349,260

(22) Filed: Jun. 16, 2021

(30) Foreign Application Priority Data
Nov. 26, 2020 (CN) 202011355883.X

(51) Int. Cl. H01L 27/32; H01L 51/00; G09G 3/3225

(52) U.S. Cl. CPC H01L 27/3276; G09G 3/3225; H01L 51/0097

(57) ABSTRACT

The present disclosure relates to the technical field of display, and discloses a display panel and a display apparatus. The display panel includes a first substrate, a power line arranged on the first substrate, and a drive circuit located at the side, facing away from the first substrate, of the power line and isolated from the power line, an orthographic projection of the power line on the first substrate is at least partially overlapped with an orthographic projection of the drive circuit on the first substrate.

### CROSS-REFERENCE TO RELATED APPLICATION

This application claims priority to Chinese Patent Application No. 202011355883.X, filed by the China National Intellectual Property Administration on Nov. 26, 2020, the entire contents of which are incorporated herein by reference.

### FIELD

The present disclosure relates to the technical field of display, in particular to a display panel and a display apparatus.

### BACKGROUND

OLED display light-emitting devices have attracted much attention due to their advantages of bright colors, good viewing angle, high contrast, fast response and low power consumption. The OLED display devices have a wider application prospective in the future display field and have a broad application space in mobile display, vehicle display, medical display and other display fields.

In recent years, the development of full screens is very rapid, which puts forward new requirements for the forms of screens. For full screen display, the influence of screen bezels is very important. However, there are many traveling lines in bezel of existing products, and some of the traveling lines are located outside a drive circuit and then connected into a pixel circuit of the display area through conductive metal. Moreover, the width of some of the traveling lines is wider, so it is difficult to realize an extremely narrow bezel. Therefore, how to arrange the lines of the product bezels to realize the design of the narrow bezels is a problem that needs to be solved at present.

### SUMMARY

Embodiments of the present disclosure disclose a display panel and a display apparatus.

In a first aspect, the embodiments of the present disclosure provide a display panel, includes:

a first substrate;

a power line arranged on the first substrate; and

a drive circuit located at a side, facing away from the first substrate, of the power line and isolated from the power line; an orthographic projection of the power line on the first substrate is at least partially overlapped with an orthographic projection of the drive circuit on the first substrate.

According to the display panel, the display panel is divided into a display area and a peripheral wiring area around the display area. The display panel includes the first substrate, the power line and the drive circuit are arranged on the first substrate, and the drive circuit is arranged in the peripheral wiring area; further, the power line and the drive circuit are arranged in different layers; and the power line is arranged at a side, facing the first substrate, of the drive circuit, that is, the power line is arranged under the drive circuit, the power line is partially overlapped with the drive circuit, the power line is configured to provide an electrical signal to a pixel unit of the display area, and generally, a width of the power line is large.

Optionally, the display panel further includes a cathode line arranged at a side, facing away from the power line, of the drive circuit;

The power line includes a low-voltage power line and a high-voltage power line, and the high-voltage power line is at a side, facing the display area of the display panel, of the low-voltage power line; an orthographic projection of the low-voltage power line on the first substrate is at least partially overlapped with an orthographic projection of the drive circuit on the first substrate, and the low-voltage power line is connected with the cathode line through a conductive connecting layer; and the high-voltage power line is configured to access the display area of the display panel to be electrically connected with the pixel unit of the display panel.

Optionally, a side edge, facing away from the display area, of the low-voltage power line extends out of a side edge, facing away from the display area, of the drive circuit the conductive connecting layer is in lapping connection with the side edge, facing away from the display area, of the low-voltage power line through a first via hole, and the conductive connecting layer is in lapping connection with the cathode line.

Optionally, a connecting metal is formed at a position, corresponding to the first via hole, of the low-voltage power line, the connecting metal is electrically connected with the low-voltage power line, and the conductive connecting layer is electrically connected with the connecting metal through the first via hole.

Optionally, a step structure is formed on an inner wall of the first via hole, and a position, on the inner wall of the first via hole, of the conductive connecting layer is arranged along a surface of the inner wall of the first via hole.

Optionally, an orthographic projection of the high-voltage power line on the first substrate is partially overlapped with the orthographic projection of the drive circuit on the first substrate; or

the orthographic projection of the high-voltage power line on the first substrate is not overlapped with the orthographic projection of the drive circuit on the first substrate.

Optionally, the high-voltage power line accesses the display area through a conductive line;

the conductive line is located at a side, facing away from the first substrate, of the high-voltage power line, and the conductive line is electrically connected with the high-voltage power line through a second via hole.

Optionally, the display panel further includes a second substrate stacked with the first substrate, the first substrate and the second substrate are both flexible substrates, the power line is between the first substrate and the second substrate, and the drive circuit is at the side, away from the power line, of the second substrate.

Optionally, a layer thickness of the second substrate is smaller than a layer thickness of the first substrate.

Based on the same application concept, the present disclosure also provides a display apparatus, including any display panel provided by the above technical solution.

### BRIEF DESCRIPTION OF THE DRAWINGS

FIG. 1 is a schematic structural diagram of a local film layer of a display panel provided by an embodiment of the present disclosure.

FIG. 2 is a schematic structural diagram of a film layer at a first via hole in a display panel provided by an embodiment of the present disclosure.

Icons: 1—first substrate; 2—low-voltage power line; 3—high-voltage power line; 4—drive circuit; 5—cathode line; 6—conductive connecting layer; 7—first via hole; 8—connecting metal; 9—step structure; 10—conductive line; 11—second via hole; 12—second substrate; and 13—encapsulation film layer.

### DETAILED DESCRIPTION OF THE EMBODIMENTS

The technical solutions in embodiments of the present disclosure will be clearly and fully described in combination with the accompanying drawings. Obviously, the described embodiments are only part of the embodiments of the present disclosure, instead of all the embodiments. Based on the embodiments in the present disclosure, all other embodiments obtained by those of ordinary skill in the art without creative work belong to the protection scope of the present disclosure.

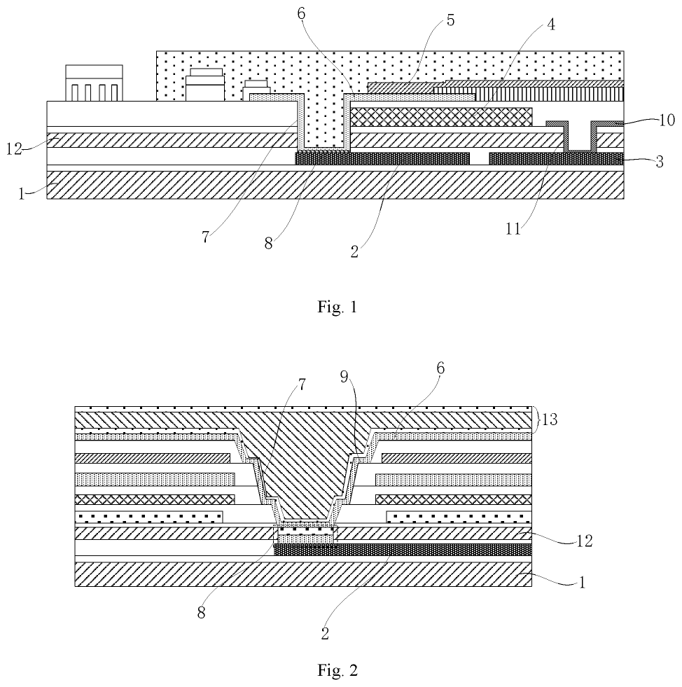

As shown in FIG. 1 and FIG. 2, Embodiments of the present disclosure provide a display panel, including a first substrate 1, a power line arranged on the first substrate 1, and a drive circuit 4 located at a side, facing away from the first substrate 1, of the power line and isolated from the power line, an orthographic projection of the power line on the first substrate 1 is at least partially overlapped with an orthographic projection of the drive circuit 4 on the first substrate 1.

According to the display panel, the display panel is divided into a display area and a peripheral wiring area around the display area. The display panel includes the first substrate 1, the power line and the drive circuit 4 are arranged on the first substrate 1, the drive circuit 4 is arranged in the peripheral wiring area, the power line and the drive circuit 4 are arranged in different layers; and the power line is arranged at the side, facing the first substrate 1, of the drive circuit 4, that is, the power line is arranged under the drive circuit 4, the power line is partially overlapped with the drive circuit 4, the power line is configured to provide an electrical signal to a pixel unit of the display area, and generally, width of the power line is large.

According to the embodiments, the power line is arranged under the drive circuit 4, and the power line and the drive circuit 4 are arranged in different layers, so that width arranged in parallel with the drive circuit 4 may be effectively reduced, and width of the peripheral wiring area is greatly reduced, which is conducive to narrow bezel design of products and realization of design of an ultra narrow bezel.

Therefore, the power line in the display panel is arranged under the drive circuit, and the power line and the drive circuit are arranged in different layers, so that the width arranged in parallel with the drive circuit may be effectively reduced, and the width of the peripheral wiring area may be effectively reduced, which is conducive to the narrow bezel design of the products and the realization of design of the ultra narrow bezel.

As shown in FIG. 1, the display panel further includes a cathode line 5 arranged at the side, facing away from the power line, of the drive circuit 4; the power line includes a low-voltage power line 2 and a high-voltage power line 3, and the high-voltage power line 3 is at a side, facing a display area of the display panel, of the low-voltage power line 2; an orthographic projection of the low-voltage power line 2 on the first substrate 1 is at least partially overlapped with an orthographic projection of the drive circuit 4 on the first substrate 1.

In some embodiments, the low-voltage power line 2 is connected with the cathode line 5 through a conductive connecting layer 6, and the cathode line 5 is electrically connected with a cathode in the display area; and the high-voltage power line 3 is configured to access the display area of the display panel to be electrically connected with the pixel unit of the display panel.

In some embodiments, for connection between the low-voltage power line 2 and the cathode line 5, a side edge, facing away from the display area, of the low-voltage power line 2 may be arranged to extend out of a side edge, facing away from the display area, of the drive circuit 4, that is to say, a side edge part, facing away from the display area, of the low-voltage power line 2 extends out of the side edge of the drive circuit 4, and a part of the side edge part is exposed, the conductive connecting layer 6 is in lapping connection with the side edge, facing away from the display area, of the low-voltage power line 2 through a first via hole 7, for example, as show in FIG. 1, the side edge, facing away from the display area, of the low-voltage power line 2 is a portion in the low-voltage power line 2 corresponding to the first via hole 7, and the conductive connecting layer 6 is in lapping connection with a surface, facing away from the first substrate, of the side edge of the low-voltage power line 2.

In some embodiments, the conductive connecting layer 6 is in lapping connection with the cathode line 5, and an overlapping area of the conductive connecting layer 6 and the cathode line 5 is located above the drive circuit 4.

In some embodiments, in the above display panel, the conductive connecting layer 6 may be a conductive layer prepared in the same layer as an anode. It should be noted that before formation of the conductive connecting layer 6, in a direction perpendicular to the first substrate 1, a plurality of conductive functional film layers and a plurality of insulating layers for isolating the conductive functional film layers are formed between the conductive connecting layer 6 and the low-voltage power line 2, so that the first via hole 7 is a via hole penetrating through the plurality of insulating layers and the first via hole 7 is deep.

In some embodiments, a connecting metal 8 is formed at a position, corresponding to the first via hole 7, in the low-voltage power line 2, the connecting metal 8 is electrically connected with the low-voltage power line 2, the connecting metal 8 has a certain thickness and may fill a certain height at the bottom of the first via hole 7 to reduce the depth of the first via hole 7, so that electrical connection between the conductive connecting layer 6 and the connecting metal 8 may be facilitated, which is beneficial to reduce risk of fracture of the conductive connecting layer 6 due to the excessive depth of the first via hole 7.

In some embodiments, the connecting metal 8 may be a plurality of metal laminated layers prepared with the same layer of a gate line or other metal film layers, or a single metal layer prepared with the same layer of the gate line or other metal film layers during preparation of the gate line or other metal film layers, which is not limited in the embodiments.

In some embodiments, in order to alleviate the problem that the inner wall of the first via hole 7 is steep because the first via hole 7 is too deep, as shown in FIG. 2, a step structure 9 is formed on the inner wall of the first via hole 7, the position, located on the inner wall of the first via hole 7, of the conductive connecting layer is arranged along the surface of the inner wall of the first via hole 7, the step structure 9 is formed on the inner wall of the first via hole 7 for transition to reduce slope of the inner wall of the first via hole 7, the conductive connecting layer is arranged along the surface of the inner wall of the first via hole 7, which also forms the step structure 9, so that corresponding transition is achieved to avoid steep climbing, so as to ensure climbing continuity of the conductive connecting layer and avoid fracture.

In some embodiments, the display panel further includes an encapsulation film layer 13 covering the display area and the peripheral wiring area, a relatively large overlapping hole is formed due to the fact that the first via hole 7 is deep, and an organic layer in the encapsulation film layer 13 fills the first via hole 7, which is conducive to ensuring stability of a film layer structure of the display panel.

In some embodiments, according to the display panel, the low-voltage power line 2 is overlapped with the drive circuit 4 and arranged in the peripheral wiring area, the high-voltage power line 3 may be arranged in the peripheral wiring area, so that an orthographic projection of the high-voltage power line 3 on the first substrate 1 is partially overlapped with the orthographic projection of the drive circuit 4 on the first substrate 1, a side edge part, facing the display area, of the high-voltage power line 3 extends out of the side of the drive circuit 4, and the side edge part, facing the display area, of the high-voltage power line 3 may be configured to be connected with a conductive line 10 which accesses the display area; or

the orthographic projection of the high-voltage power line 3 on the first substrate 1 may be not overlapped with the orthographic projection of the drive circuit 4 on the first substrate 1, and the high-voltage power line 3 may be arranged at the position, corresponding to the display area, in the first substrate 1, so that connection between the high-voltage power line 3 and the conductive line 10 which accesses the display area is facilitated.

It should be noted that the high-voltage power line is arranged at the side, facing the display area, of the low-voltage power line, that is, the high-voltage power line is arranged at the inner side of the low-voltage power line, which is convenient for accessing the display area. The specific arrangement position of the high-voltage power line may be designed and arranged according to actual needs, which is not limited in the embodiment.

In some embodiments, according to the display panel, the high-voltage power line 3 accesses the display area through the conductive line 10 so as to be electrically connected with the pixel unit of the display panel, the conductive line 10 is at the side, facing away from the first substrate 1, of the high-voltage power line 3, and the conductive line 10 is electrically connected with the high-voltage power line 3 through a second via hole 11.

According to the display panel, the display panel may be a flexible display panel, and the display panel may be a panel with double substrates. In some embodiments, a second substrate 12 stacked with the first substrate 1 is arranged above the first substrate 1, the first substrate 1 and the second substrate 12 are both flexible substrates, the power line is between the first substrate 1 and the second substrate 12, and the drive circuit 4 is at a side, facing away from the power line, of the second substrate 12. The first via hole 7 and the second via hole 11 for connection of the power line both may penetrate through the second substrate 12 to facilitate the connection of the power line.

In some embodiments, according to the display panel, a layer thickness of the second substrate is smaller than a layer thickness of the first substrate, which may ensure flexibility of the flexible display panel, and effectively reduce the depth of the first via hole for first power line connection, so that the climbing continuity of the conductive connecting layer in the first via hole is ensured.

Based on the same application concept, the embodiments of the present disclosure also provide a display apparatus, including any display panel provided by the above technical solution.

Obviously, those skilled in the art can make various changes and transformations for the present disclosure without departing from the spirit and scope of the present disclosure. In this case, if these changes and transformations of the present disclosure belong to the scope of claims of the present disclosure and their equivalent technologies, the present disclosure is also intended to include these changes and transformations.

What is claimed is:

1. A display panel, comprising:
a first substrate;
a power line arranged on the first substrate; and
a drive circuit located at a side, facing away from the first substrate, of the power line and isolated from the power line;
wherein an orthographic projection of the power line on the first substrate is at least partially overlapped with an orthographic projection of the drive circuit on the first substrate.

2. The display panel according to claim 1, further comprising:
a cathode line arranged at a side, facing away from the power line, of the drive circuit;
wherein the power line comprises:
a low-voltage power line, and
a high-voltage power line;
wherein the high-voltage power line is at a side, facing a display area of the display panel, of the low-voltage power line;
an orthographic projection of the low-voltage power line on the first substrate is at least partially overlapped with the orthographic projection of the drive circuit on the first substrate;
the low-voltage power line is connected with the cathode line through a conductive connecting layer; and
the high-voltage power line is configured to access the display area of the display panel to be electrically connected with a pixel unit of the display panel.

3. The display panel according to claim 2, wherein:
a side edge, facing away from the display area, of the low-voltage power line extends out of a side edge, facing away from the display area, of the drive circuit;
the conductive connecting layer is in lapping connection with the side edge, facing away from the display area, of the low-voltage power line through a first via hole; and
the conductive connecting layer is in lapping connection with the cathode line.

4. The display panel according to claim 3, wherein:
a connecting metal is formed at a position, corresponding to the first via hole, in the low-voltage power line;
the connecting metal is electrically connected with the low-voltage power line; and
the conductive connecting layer is electrically connected with the connecting metal through the first via hole.

5. The display panel according to claim 3, wherein:
a step structure is formed on an inner wall of the first via hole, and
a position, on the inner wall of the first via hole, of the conductive connecting layer is arranged along a surface of the inner wall of the first via hole.

6. The display panel according to claim 2, wherein:
an orthographic projection of the high-voltage power line on the first substrate is partially overlapped with the orthographic projection of the drive circuit on the first substrate; or
the orthographic projection of the high-voltage power line on the first substrate is not overlapped with the orthographic projection of the drive circuit on the first substrate.

7. The display panel according to claim 2, wherein:
the high-voltage power line accesses the display area through a conductive line;
the conductive line is at a side, facing away from the first substrate, of the high-voltage power line; and
the conductive line is electrically connected with the high-voltage power line through a second via hole.

8. The display panel according to claim 1, further comprising:
a second substrate stacked with the first substrate;
wherein the first substrate and the second substrate are both flexible substrates, the power line is between the first substrate and the second substrate, and the drive circuit is at a side, facing away from the power line, of the second substrate.

9. The display panel according to claim 8, wherein a layer thickness of the second substrate is smaller than a layer thickness of the first substrate.

10. A display apparatus, comprising a display panel, wherein the display panel comprises:
a first substrate;
a power line arranged on the first substrate; and
a drive circuit located at a side, facing away from the first substrate, of the power line and isolated from the power line; and
an orthographic projection of the power line on the first substrate is at least partially overlapped with an orthographic projection of the drive circuit on the first substrate.

11. The display apparatus according to claim 10, wherein the display panel further comprises:
a cathode line arranged at a side, facing away from the power line, of the drive circuit;
wherein the power line comprises:
a low-voltage power line, and
a high-voltage power line;
wherein the high-voltage power line is at a side, facing a display area of the display panel, of the low-voltage power line;
an orthographic projection of the low-voltage power line on the first substrate is at least partially overlapped with the orthographic projection of the drive circuit on the first substrate;
the low-voltage power line is connected with the cathode line through a conductive connecting layer; and
the high-voltage power line is configured to access a display area of the display panel to be electrically connected with a pixel unit of the display panel.

12. The display apparatus according to claim 11, wherein:
a side edge, facing away from the display area, of the low-voltage power line extends out of a side edge, facing away from the display area, of the drive circuit;
the conductive connecting layer is in lapping connection with the side edge, facing away from the display area, of the low-voltage power line through a first via hole; and
the conductive connecting layer is in lapping connection with the cathode line.

13. The display apparatus according to claim 12, wherein:
a connecting metal is formed at a position, corresponding to the first via hole, of the low-voltage power line;
the connecting metal is electrically connected with the low-voltage power line; and
the conductive connecting layer is electrically connected with the connecting metal through the first via hole.

14. The display apparatus according to claim 12, wherein a step structure is formed on an inner wall of the first via hole, and a position, on the inner wall of the first via hole, of the conductive connecting layer is arranged along a surface of the inner wall of the first via hole.

15. The display apparatus according to claim 11, wherein:
an orthographic projection of the high-voltage power line on the first substrate is partially overlapped with the orthographic projection of the drive circuit on the first substrate; or
the orthographic projection of the high-voltage power line on the first substrate is not overlapped with the orthographic projection of the drive circuit on the first substrate.

16. The display apparatus according to claim 11, wherein:
the high-voltage power line accesses the display area through a conductive line;
the conductive line is at a side, facing away from the first substrate, of the high-voltage power line; and
the conductive line is electrically connected with the high-voltage power line through a second via hole.

17. The display apparatus according to claim 10, wherein the display panel further comprises:
a second substrate stacked with the first substrate,
wherein the first substrate and the second substrate are both flexible substrates, the power line is between the first substrate and the second substrate, and the drive circuit is at a side, facing away from the power line, of the second substrate.

18. The display apparatus according to claim 17, wherein a layer thickness of the second substrate is smaller than a layer thickness of the first substrate.
